(19) United States
(12) Patent Application Publication
(10) Pub. No.: US 2026/0082920 A1
(43) Pub. Date: Mar. 19, 2026

(54) CHIP-STACKED DEVICE

(71) Applicant: NuFlare Technology, Inc., Yokohama-shi (JP)

(72) Inventors: Yutaka ONOZUKA, Yokohama (JP); Kenichi KATAOKA, Setagaya (JP)

(73) Assignee: NuFlare Technology, Inc., Yokohama-shi (JP)

(21) Appl. No.: 19/271,959

(22) Filed: Jul. 17, 2025

(30) Foreign Application Priority Data
Sep. 17, 2024 (JP) 2024-160323

(51) Int. Cl. H01L 23/00; H01L 23/48

(52) U.S. Cl. CPC H10W 42/121; H10W 20/20; H10W 90/722

(57) ABSTRACT

A first chip includes a first substrate which includes a first outer peripheral surface and a first array surface surrounded by the first outer peripheral surface, and a first wiring layer provided on the first substrate. A second chip including a second substrate which includes a second outer peripheral surface facing the first outer peripheral surface and a second array surface facing the first array surface, which is surrounded by the second outer peripheral surface, and a second wiring layer provided on the second array surface. A plurality of connection portions is provided between the first array surface and the second array surface. The plurality of connection portions is configured to electrically connect the first wiring layer and the second wiring layer. The second substrate includes a recessed portion provided in the second outer peripheral surface.

### CROSS-REFERENCE TO RELATED APPLICATIONS

This application is based upon and claims the benefit of priority from Japanese Patent Application No.2024-160323, filed on September 17, 2024; the entire contents of which are incorporated herein by reference.

### FIELD

Embodiments of the invention relate to a chip-stacked device.

### BACKGROUND

A device in which two chips are stacked by metal-to-metal bonding is known.

### SUMMARY

An object of embodiments of the invention is to provide a chip-stacked device in which a defect caused by breakage of the outer peripheral region of the chip can be reduced.

According to an embodiment of the invention, a chip-stacked device includes: a first chip including a first substrate which includes a first outer peripheral surface and a first array surface surrounded by the first outer peripheral surface, and a first wiring layer provided on the first substrate; a second chip including a second substrate which includes a second outer peripheral surface facing the first outer peripheral surface and a second array surface facing the first array surface, which is surrounded by the second outer peripheral surface, and a second wiring layer provided on the second array surface; and a plurality of connection portions, which is provided between the first array surface and the second array surface, configured to electrically connect the first wiring layer and the second wiring layer. The second substrate includes a recessed portion provided in the second outer peripheral surface.

### BRIEF DESCRIPTION OF THE DRAWINGS

FIG. 1 is a schematic plan view of a chip-stacked device according to embodiments;

FIG. 2 is a schematic cross-sectional view of a chip-stacked device according to a first embodiment;

FIG. 3 is a schematic cross-sectional view of a chip-stacked device according to a second embodiment;

FIG. 4 is a schematic cross-sectional view of a chip-stacked device according to a third embodiment;

FIG. 5 is a schematic cross-sectional view of a chip-stacked device according to a fourth embodiment;

FIG. 6 is a schematic cross-sectional view of a chip-stacked device according to a fifth embodiment;

FIG. 7 is a schematic cross-sectional view of a chip-stacked device according to a sixth embodiment; and

FIG. 8A to FIG. 10B are schematic cross-sectional views showing a method for manufacturing a second chip according to an embodiment.

### DETAILED DESCRIPTION

Embodiments will now be described with reference to the drawings.

The drawings are schematic or conceptual, and the relationship between the thickness and width of each portion, the proportions of sizes among portions, and so on are not necessarily the same as the actual values. Even the dimensions and proportion of the same portion may be illustrated differently depending on the drawing.

The same or similar elements are denoted by the same reference numerals.

### First Embodiment

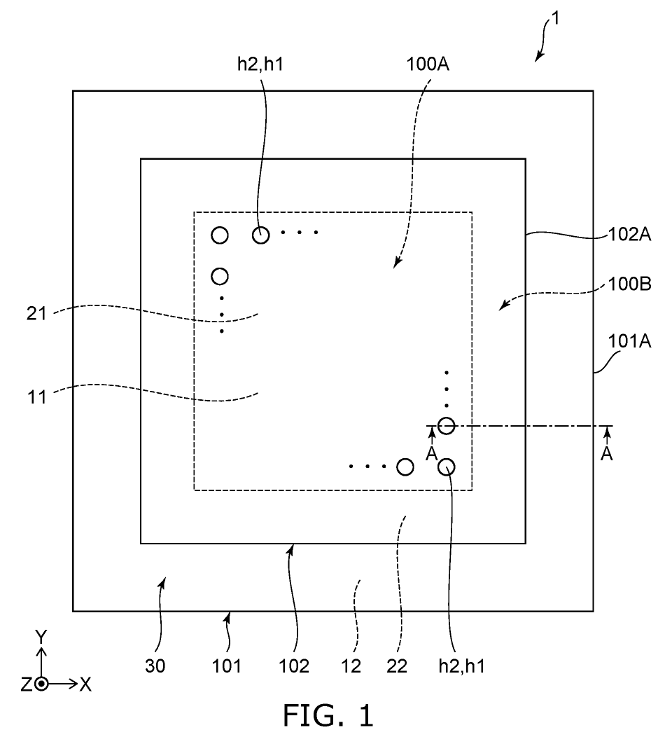

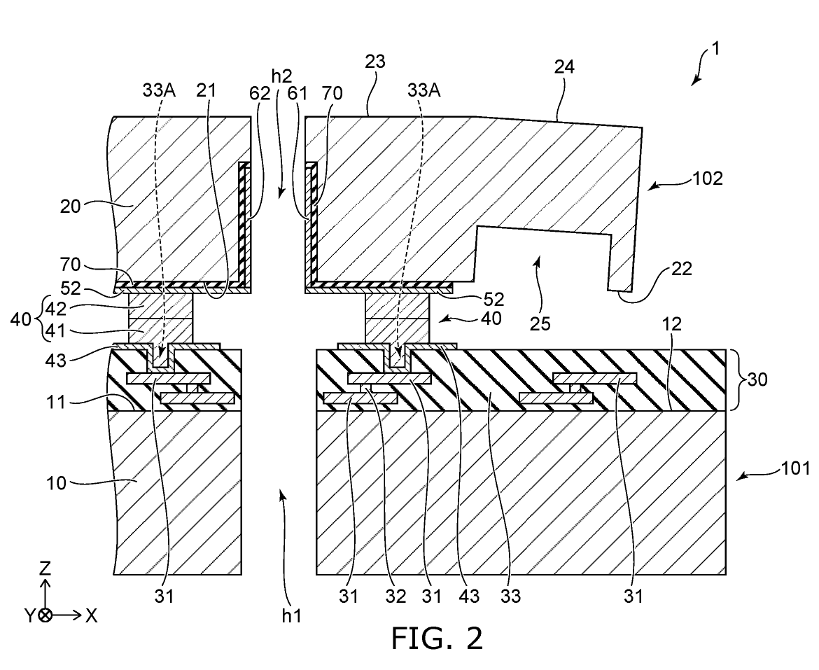

A chip-stacked device 1 according to an embodiment will be described with reference to FIG. 1 and FIG. 2.

As shown in FIG. 1, the chip-stacked device 1 includes an array region 100A and an outer peripheral region 100B. In FIG. 1, the boundary between the array region 100A and the outer peripheral region 100B is virtually depicted in a dashed line. In plan view, the outer peripheral region 100B surrounds the array region 100A.

The chip-stacked device 1 includes a first chip 101 and a second chip 102. The planar size of the second chip 102 is smaller than the planar size of the first chip 101, and an outer edge 102A of the second chip 102 is located inside an outer edge 101A of the first chip 101.

FIG. 2 illustrates a cross section taken along line A-A in FIG. 1. The first chip 101 and the second chip 102 are stacked in a first direction Z. Two directions orthogonal to each other in a plane orthogonal to the first direction Z are defined as a second direction X and a third direction Y.

The first chip 101 includes a first substrate 10 and a wiring portion 30. The wiring portion 30 includes at least a first wiring layer 31 in one layer. FIG. 2 shows an example in which the wiring portion 30 has a multilayer wiring structure.

The first substrate 10 is, for example, a silicon substrate including a large-scale integration (LSI) circuit. The first substrate 10 includes a first outer peripheral surface 12 and a first array surface 11 surrounded by the first outer peripheral surface 12 in plan view. The first outer peripheral surface 12 is located in the outer peripheral region 100B, and the first array surface 11 is located in the array region 100A.

The wiring portion 30 is continuously provided on the first array surface 11 and the first outer peripheral surface 12. The wiring portion 30 includes the first wiring layer 31 and an insulating layer 33. The first wiring layer 31 is provided in the insulating layer 33. When first wiring layers 31 in multiple layers are provided, the wiring portion 30 further includes a conductive via 32 connecting the first wiring layers 31 in different layers to each other.

The second chip 102 includes a second substrate 20. The second substrate 20 is, for example, a silicon substrate. The second substrate 20 includes a second outer peripheral surface 22 and a second array surface 21 surrounded by the second outer peripheral surface 22 in plan view. The second outer peripheral surface 22 is located in the outer peripheral region 100B and faces the first outer peripheral surface 12 of the first substrate 10 in the first direction Z. The second array surface 21 is located in the array region 100A and faces the first array surface 11 of the first substrate 10 in the first direction Z.

The second substrate 20 further includes a third array surface 23 located on a side opposite to the second array surface 21 in the first direction Z, and a third outer peripheral surface 24 located on a side opposite to the second outer peripheral surface 22 in the first direction Z.

The second substrate 20 further includes a recessed portion 25 provided in the second outer peripheral surface 22. The recessed portion 25 includes an opening on a side facing the first chip 101. The recessed portion 25 is not connected to the third outer peripheral surface 24.

The second chip 102 further includes a second wiring layer 52. For example, the second wiring layer 52 is provided on the second array surface 21 of the second substrate 20 with an insulating film 70 interposed therebetween.

The chip-stacked device 1 according to the first embodiment further includes a plurality of connection portions 40 disposed in the array region 100A. The plurality of connection portions 40 are provided between the first array surface 11 and the second array surface 21 in the array region 100A, and electrically connect the first wiring layer 31 of the first chip 101 and the second wiring layer 52 of the second chip 102. The connection portion 40 is not provided in the outer peripheral region 100B.

The connection portion 40 is formed by bonding a first metal portion 41 provided on the first chip 101 side and a second metal portion 42 provided on the second chip 102 side. The first metal portion 41 and the second metal portion 42 include, for example, gold, and the connection portion 40 is a gold-to-gold bonded body.

For example, the first metal portion 41 is electrically connected to the first wiring layer 31 via a metal film 43. The metal film 43 is provided on the surface of the insulating layer 33 and in a connection hole 33A reaching the first wiring layer 31 from the surface of the insulating layer 33, and is connected to the first wiring layer 31 in the connection hole 33A. The first metal portion 41 is connected to the metal film 43 on the surface of the insulating layer 33. Further, a part of the first metal portion 41 is connected to the metal film 43 in the connection hole 33A.

The second metal portion 42 is bonded to the second wiring layer 52 and is electrically connected to the second wiring layer 52.

The first chip 101 further includes a first through hole h1 penetrating the first substrate 10 and the wiring portion 30 in the first direction Z. A plurality of first through holes h1 are disposed in the array region 100A.

The second chip 102 further includes a second through hole h2, a first electrode 61, and a second electrode 62.

A plurality of second through holes h2 are disposed in the array region 100A. The second through hole h2 penetrates the second substrate 20 in the first direction Z, extends between the plurality of connection portions 40, and is continuous with the first through hole h1. As shown in FIG. 1, the second through hole h2 overlaps the first through hole h1 in plan view.

The first through hole h1 and the second through hole h2 are not provided in the outer peripheral region 100B. With the outer peripheral region 100B in which the first through hole h1 and the second through hole h2 are not provided, the strength of the first chip 101 and the second chip 102 can be increased.

Further, since the outer peripheral region 100B does not include through holes, a suction surface for holding each chip can be secured in the outer peripheral region 100B. For example, the second chip 102 can be held by sucking, with a nozzle, the third outer peripheral surface 24 of the second substrate 20 or a region, in the second outer peripheral surface 22, in which the recessed portion 25 is not formed. Further, an alignment mark used at the time of bonding to the first chip 101 can be formed on the third outer peripheral surface 24 or in a region, in the second outer peripheral surface 22, in which the recessed portion 25 is not formed.

The first electrode 61 is provided on the inner wall of the second through hole h2 with the insulating film 70 interposed therebetween, and is electrically connected to the second wiring layer 52 provided on the second array surface 21. The second electrode 62 is provided on the inner wall of the second through hole h2 at a position facing the first electrode 61 with the insulating film 70 interposed therebetween, and is electrically connected to the second wiring layer 52 provided on the second array surface 21. The second wiring layer 52 connected to the first electrode 61 and the second wiring layer 52 connected to the second electrode 62 are separated on the insulating film 70. A first system in which the first wiring layer 31 and the first electrode 61 are electrically connected to each other via the connection portion 40 and the second wiring layer 52 and a second system in which the first wiring layer 31 and the second electrode 62 are electrically connected to each other via the connection portion 40 and the second wiring layer 52 can be controlled independently of each other. For example, an electric field can be generated in the second through hole h2 by applying a positive potential to the first system and applying a ground potential to the second system.

The first metal portion 41 and the second metal portion 42 are directly bonded to each other by bringing the first metal portion 41 provided on the first chip 101 side and the second metal portion 42 provided on the second chip 102 side into contact with each other, applying a load in the first direction Z to the first metal portion 41 and the second metal portion 42, and heating the first metal portion 41 and the second metal portion 42, to form the connection portion 40. For example, during a process of, for example, temporary bonding before main bonding, there is a possibility that a part of the second substrate 20 on the outer edge side is chipped and a fragment of the substrate enters the gap between the second outer peripheral surface 22 of the second substrate 20 and the first outer peripheral surface 12 of the first substrate 10. There is also a possibility that, for example, foreign matter produced outside enters the gap between the second outer peripheral surface 22 of the second substrate 20 and the first outer peripheral surface 12 of the first substrate 10. Examples of the foreign matter produced outside include organic matter and dust, such as fibers, produced from workers and work clothes. Examples of the foreign matter produced outside further include fragments (metal, plastic, ceramic, etc.) of minute components produced from other portions of the device. When the first chip 101 and the second chip 102 are bonded to each other by applying a load in the first direction Z to the first chip 101 and the second chip 102, a fragment or the like entering the gap between the second outer peripheral surface 22 and the first outer peripheral surface 12 may be sandwiched between the second outer peripheral surface 22 and the first outer peripheral surface 12 and pressed against the first wiring layer 31 provided on the first outer peripheral surface 12 of the first substrate 10, thereby causing damage to the first wiring layer 31. In particular, in the outer peripheral region 100B in which the plurality of connection portions 40 are not disposed, the outer peripheral portion of the second substrate 20 tilts toward the first chip 101 by the load in the first direction Z, and the height of the gap between the second outer peripheral surface 22 and the first outer peripheral surface 12 is likely to be narrowed, as shown in FIG. 2. As a result, the fragment or the like entering the gap between the second outer peripheral surface 22 and the first outer peripheral surface 12 is more likely to be pressed against the first wiring layer 31 with a strong force.

According to the embodiment, the recessed portion 25 is provided in the second outer peripheral surface 22 of the second substrate 20. Therefore, even if a fragment or the like enters the gap between the second outer peripheral surface 22 and the first outer peripheral surface 12, the fragment or the like is located in the recessed portion 25, and therefore, is less likely to be sandwiched between the second chip 102 and the first chip 101 with a strong force. Accordingly, a defect caused by breakage of the outer peripheral region of the chip, such as the first wiring layer 31, can be reduced.

Further, when the height of the gap between the first chip 101 and the second chip 102 obtained by providing the recessed portion 25 is made larger than the height of the fragment or the like entering the gap, even if the fragment or the like is sandwiched between the second chip 102 and the first chip 101, the stress generated in the first wiring layer 31 can be reduced.

The depth (the length in the first direction Z) of the recessed portion 25 is preferably greater than or equal to the height of the gap, in the first direction Z, between the first chip 101 and the second chip 102 in the array region 100A after bonding.

The inventors have confirmed that when the height of the gap, in the first direction Z, between the first chip 101 and the second chip 102 in the array region 100A after bonding is 3 μm, a fragment having a size of about 5 μm enters the gap between the first outer peripheral surface 12 and the second outer peripheral surface 22. The inventors have also confirmed, in the device, a device defect caused by breakage of the first wiring layer 31 on the first outer peripheral surface 12. In view of such facts, it is assumed that a fragment having a size of several μm enters the gap between the first outer peripheral surface 12 and the second outer peripheral surface 22, and the depth of the recessed portion 25 is preferably 10 μm or more. Note that the thickness of the second substrate 20 is, for example, 130 μm.

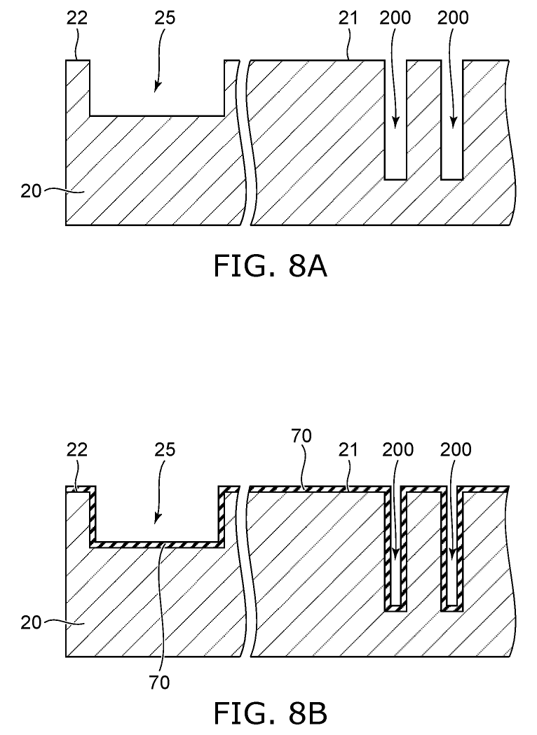

A method for manufacturing the second chip 102 in the chip-stacked device 1 described above will be described with reference to FIG. 8A to FIG. 10B.

As shown in FIG. 8A, a plurality of trenches 200 are formed in the second array surface 21 of the second substrate 20, and the recessed portion 25 is formed in the second outer peripheral surface 22 of the second substrate 20. The depth of the recessed portion 25 is shallower than the depth of the trenches 200. The trenches 200 and the recessed portion 25 can be formed by, for example, the reactive ion etching (RIE) method.

After the trenches 200 and the recessed portion 25 are formed, the insulating film 70 is formed on the second array surface 21, the second outer peripheral surface 22, the inner wall of each trench 200, and the inner wall of the recessed portion 25, as shown in FIG. 8B. The insulating film 70 is, for example, a silicon oxide film. After the insulating film 70 is formed, for example, a liner-shaped metal film (not illustrated), such as a titanium nitride film, may be formed on the insulating film 70 on the second array surface 21, the second outer peripheral surface 22, the inner wall of each trench 200, and the inner wall of the recessed portion 25.

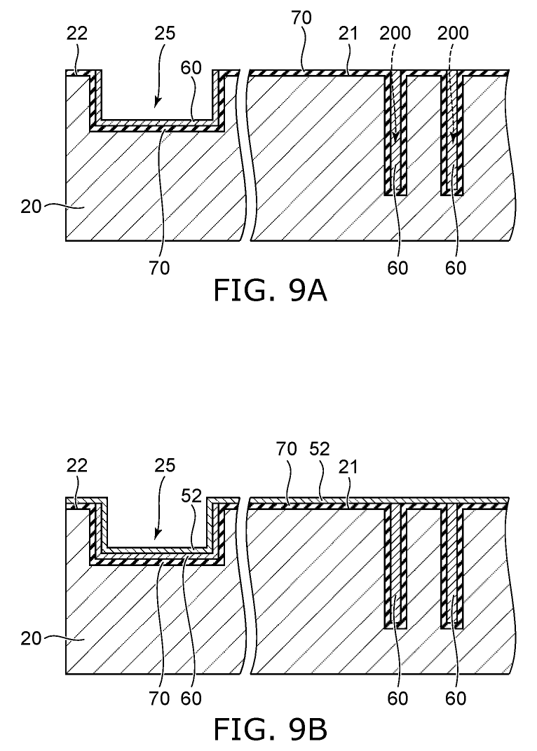

After the insulating film 70 (or the metal film) is formed, an electrode film 60 is formed on the inner side of the insulating film 70 (or the metal film) in each trench 200 and the inner side of the insulating film 70 (or the metal film) in the recessed portion 25, as shown in FIG. 9A. The electrode film 60 is formed on the entire surface of the insulating film 70 (or the metal film), and thereafter, the electrode film 60 on the insulating film 70 on the second array surface 21 and the electrode film 60 (and the metal film) on the insulating film 70 on the second outer peripheral surface 22 are removed. The electrode film 60 (and the metal film) is embedded in each trench 200. The upper surface of the electrode film 60 (and the metal film) in each trench 200 is exposed from the insulating film 70. The electrode film 60 is, for example, a tungsten film.

After the electrode film 60 is formed, the second wiring layer 52 is formed on the second outer peripheral surface 22, in the recessed portion 25, and on the second array surface 21, as shown in FIG. 9B. On the second array surface 21, the second wiring layer 52 is in contact with the upper surface of the electrode film 60. The second wiring layer 52 on the second array surface 21 and the second wiring layer 52 in the recessed portion 25 are separated from each other so that the second wiring layer 52 in the recessed portion 25 is unable to be electrically connected to the electrode film 60.

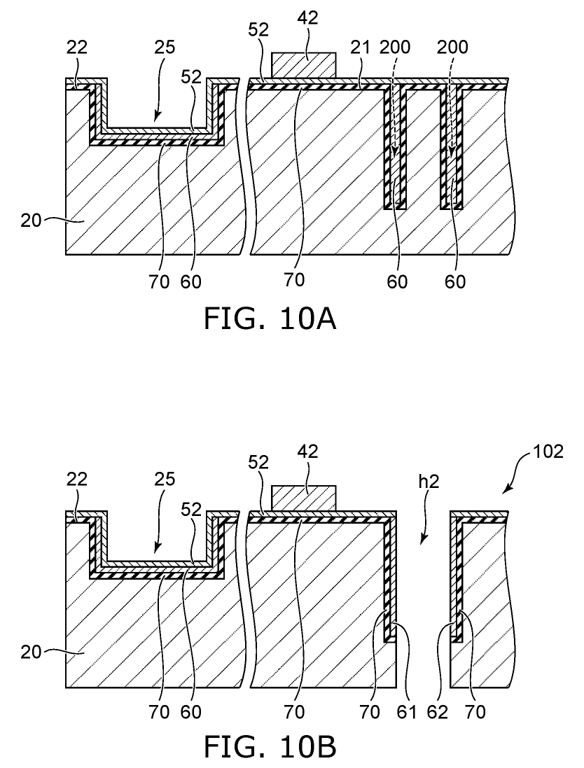

After the second wiring layer 52 is formed, the second metal portion 42 is formed on the second wiring layer 52 of the second array surface 21, as shown in FIG. 10A.

After the second metal portion 42 is formed, the second through hole h2 is formed in a portion between adjacent trenches 200, as shown in FIG. 10B. The second substrate 20 and the insulating film 70 between the adjacent trenches 200 are removed, and a pair of electrode films 60 facing each other are exposed in the second through hole h2. One of the pair of electrode films 60 exposed in the second through hole h2 serves as the first electrode 61, and the other serves as the second electrode 62.

The second wiring layer 52, the electrode film 60, and the insulating film 70 remain in the recessed portion 25. Alternatively, the second wiring layer 52, the electrode film 60, and the insulating film 70 in the recessed portion 25 may be removed.

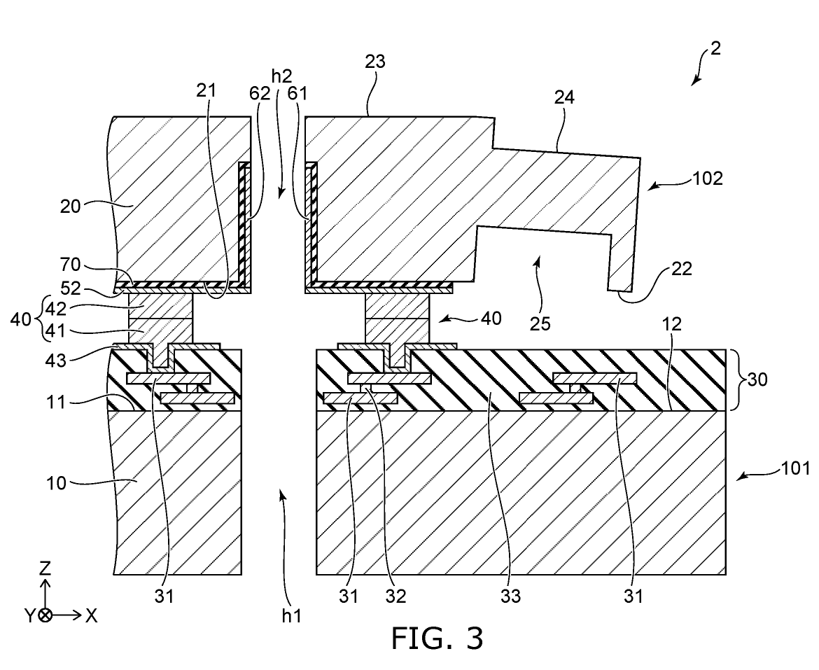

Chip-stacked devices according to other embodiments will be described below with reference to FIG. 3 to FIG. 7. Regarding the chip-stacked devices according to other embodiments, a configuration different from that of the chip-stacked device 1 according to the first embodiment will be mainly described. The plan view shown in FIG. 1 is also applicable to the chip-stacked devices according to other embodiments described below.

### Second Embodiment

FIG. 3 is a schematic cross-sectional view of a chip-stacked device 2 according to a second embodiment.

In the chip-stacked device 2 according to the second embodiment, a step is formed between the third array surface 23 and the third outer peripheral surface 24 so that the third outer peripheral surface 24 of the second substrate 20 is recessed with respect to the third array surface 23.

When the first chip 101 and the second chip 102 are bonded by applying a load in the first direction Z to the first chip 101 and the second chip 102, the third array surface 23 and the third outer peripheral surface 24 of the second substrate 20 are pressed by a plate-shaped member toward the first chip 101. Since the step is formed between the third array surface 23 and the third outer peripheral surface 24, the third outer peripheral surface 24 is less likely to be pressed by the plate-shaped member. Accordingly, the outer peripheral portion of the second substrate 20 is less likely to tilt toward the first chip 101, the height of the gap between the second outer peripheral surface 22 and the first outer peripheral surface 12 can be prevented from being narrowed, and a fragment entering the gap between the second outer peripheral surface 22 and the first outer peripheral surface 12 can be less likely to be pressed against the first wiring layer 31 with a strong force.

### Third Embodiment

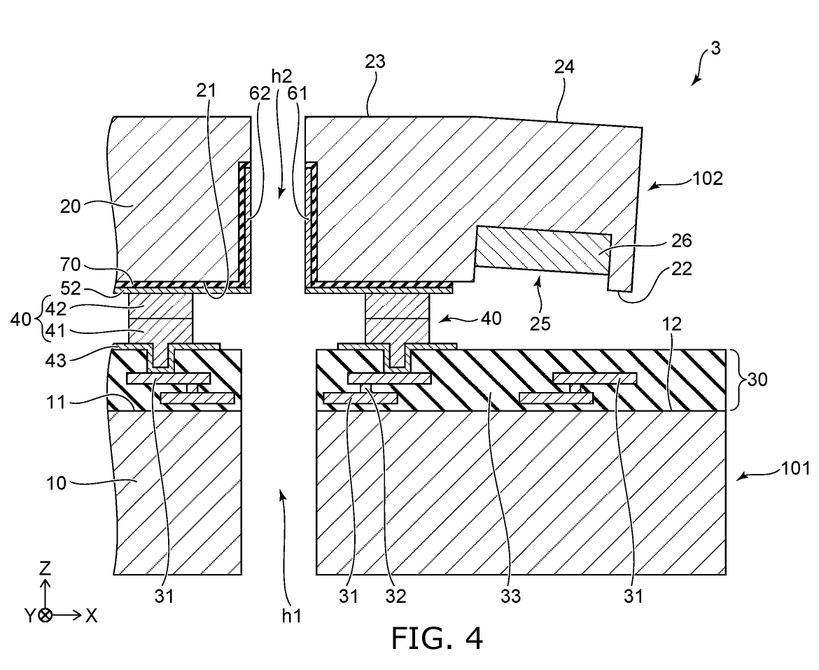

FIG. 4 is a schematic cross-sectional view of a chip-stacked device 3 according to a third embodiment.

The second chip 102 in the chip-stacked device 3 according to the third embodiment further includes an outer peripheral member 26 provided in the recessed portion 25. The hardness of the outer peripheral member 26 is lower than the hardness of the first substrate 10 and the hardness of the second substrate 20. For example, the first substrate 10 and the second substrate 20 are silicon substrates, and the outer peripheral member 26 is a resin member. Alternatively, the outer peripheral member 26 may be a metal member having a hardness lower than that of the silicon substrates.

According to the third embodiment, even if a fragment enters the gap between the second outer peripheral surface 22 and the first outer peripheral surface 12, the fragment comes into contact with the outer peripheral member 26 having a hardness lower than that of the first substrate 10 and the second substrate 20, and therefore, a force with which the fragment is pressed toward the first chip 101 can be reduced. Accordingly, a defect caused by breakage of the outer peripheral region of the chip can be reduced.

### Fourth Embodiment

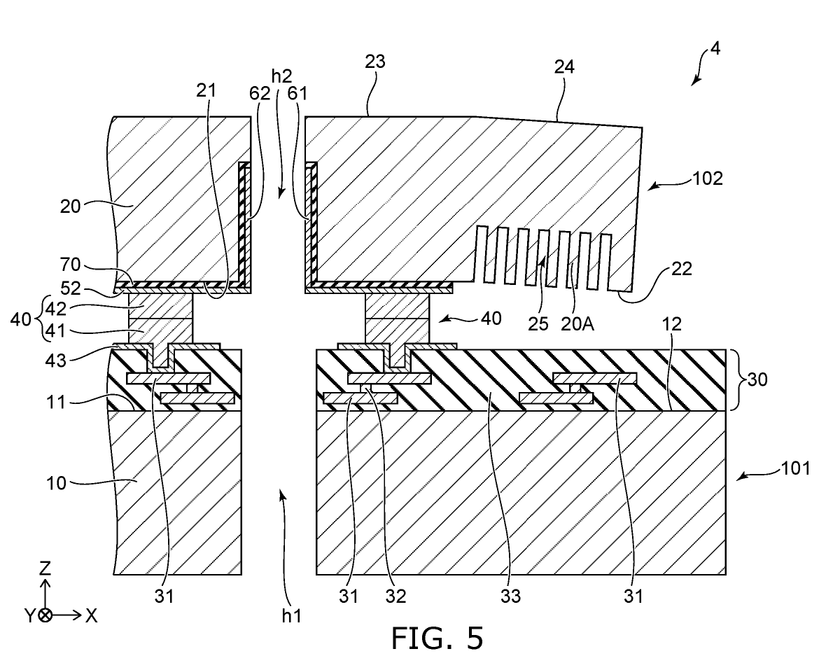

FIG. 5 is a schematic cross-sectional view of a chip-stacked device 4 according to a fourth embodiment.

In the chip-stacked device 4 according to the fourth embodiment, a part 20A of the second substrate 20 is provided in the form of pillars or fins in the recessed portion 25 provided in the second outer peripheral surface 22 of the second substrate 20.

Since the part 20A of the second substrate 20 in the form of pillars or fins coming into contact with a fragment entering the gap between the second outer peripheral surface 22 and the first outer peripheral surface 12 is bent, a force applied to the fragment can be relaxed. Accordingly, the force with which the fragment is pressed toward the first chip 101 can be reduced.

### Fifth Embodiment

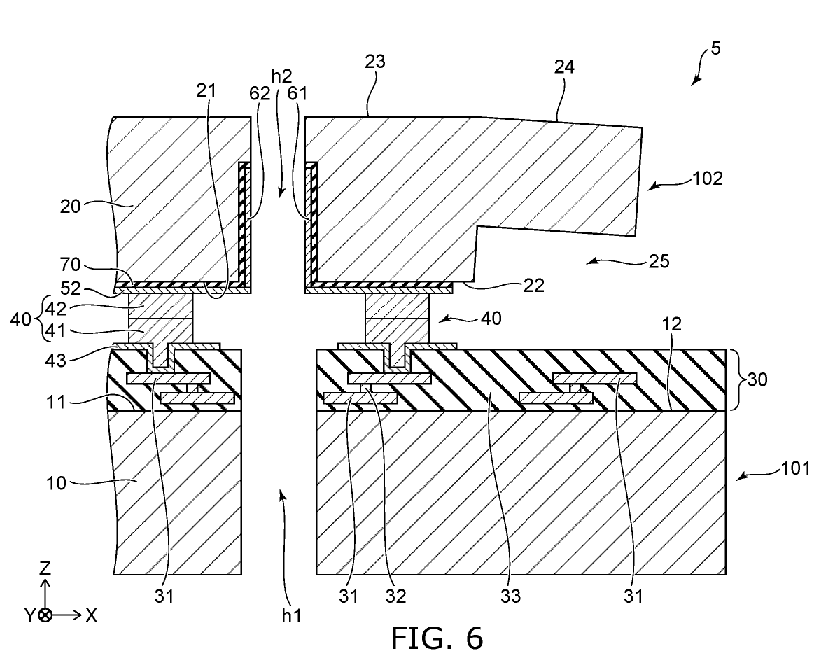

FIG. 6 is a schematic cross-sectional view of a chip-stacked device 5 according to a fifth embodiment.

In the chip-stacked device 5 according to the fifth embodiment, the side wall portion on the outer edge side is not provided in the second outer peripheral surface 22 of the second substrate 20, and the recessed portion 25 extends to the outer edge of the second substrate 20. Accordingly, a fragment is not pressed downward by the side wall portion on the outer edge side of the second substrate 20, and a defect caused by breakage of the outer peripheral region of the chip can be reduced.

### Sixth Embodiment

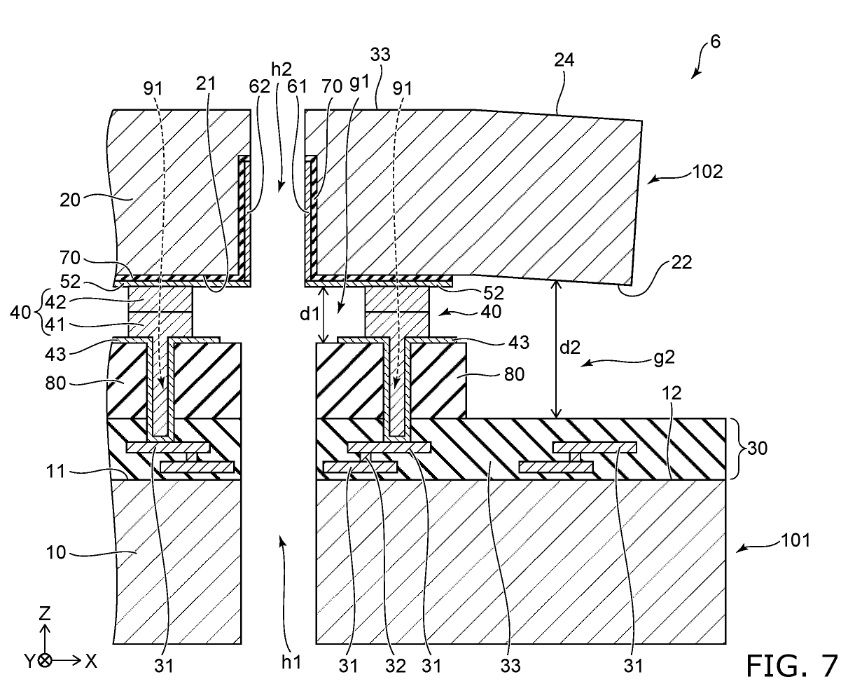

FIG. 7 is a schematic cross-sectional view of a chip-stacked device 6 according to a sixth embodiment.

The first chip 101 in the chip-stacked device 6 according to the sixth embodiment further includes an insulating member 80 provided between the first array surface 11 of the first substrate 10 and the connection portion 40. The metal film 43 is provided on the surface of the insulating member 80 and in a connection hole 91 penetrating the insulating member 80 and the insulating layer 33 of the wiring portion 30 and reaching the first wiring layer 31 from the surface of the insulating member 80, and is connected to the first wiring layer 31 in the connection hole 91. The first metal portion 41 is connected to the metal film 43 on the surface of the insulating member 80. Further, a part of the first metal portion 41 is connected to the metal film 43 in the connection hole 91. The insulating member 80 is, for example, a resin member.

A first gap g1 is formed between the insulating member 80 and the second array surface 21 of the second substrate 20, and a second gap g2 is formed between the first outer peripheral surface 12 of the first substrate 10 and the second outer peripheral surface 22 of the second substrate 20. A height d2 of the second gap g2 in the first direction Z is larger than a height d1 of the first gap g1 in the first direction Z. Accordingly, even if a fragment enters the second gap g2, the fragment is less likely to be sandwiched between the second chip 102 and the first chip 101 with a strong force. Accordingly, a defect caused by breakage of the outer peripheral region of the chip can be reduced.

### Modification of Sixth Embodiment

The insulating member 80 may be provided between the second array surface 21 of the second substrate 20 and the connection portion 40. The second wiring layer 52 is provided on the surface of the insulating member 80. The first gap g1 is formed between the insulating member 80 and the first array surface 11, the second gap g2 is formed between the first outer peripheral surface 12 and the second outer peripheral surface 22, and the height d2 of the second gap g2 is larger than the height d1 of the first gap g1.

The insulating member 80 may be provided between the first array surface 11 of the first substrate 10 and the connection portion 40, and may be provided between the second array surface 21 of the second substrate 20 and the connection portion 40. In this case, the height of the second gap between the first outer peripheral surface 12 and the second outer peripheral surface 22 is larger than the height of the first gap between the insulating member 80 of the first chip 101 and the insulating member 80 of the second chip 102.

Among the first to sixth embodiments described above, two or more embodiments can be combined as appropriate to the extent technically possible.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A chip-stacked device comprising:
a first chip including a first substrate which includes a first outer peripheral surface and a first array surface surrounded by the first outer peripheral surface, and a first wiring layer provided on the first substrate;
a second chip including a second substrate which includes a second outer peripheral surface facing the first outer peripheral surface and a second array surface facing the first array surface, which is surrounded by the second outer peripheral surface, and a second wiring layer provided on the second array surface; and
a plurality of connection portions, which is provided between the first array surface and the second array surface, configured to electrically connect the first wiring layer and the second wiring layer,
wherein the second substrate includes a recessed portion provided in the second outer peripheral surface.

2. The chip-stacked device according to claim 1, wherein
the recessed portion includes an outer peripheral member which has a hardness lower than a hardness of the first substrate and the second substrate.

3. The chip-stacked device according to claim 2, wherein
the first substrate and the second substrate are silicon substrates, and
the outer peripheral member is a resin member.

4. The chip-stacked device according to claim 1, wherein
the second substrate further includes a third array surface located on a side opposite to the second array surface and a third outer peripheral surface located on a side opposite to the second outer peripheral surface, and a step which is formed between the third array surface and the third outer peripheral surface so that the third outer peripheral surface is recessed with respect to the third array surface.

5. The chip-stacked device according to claim 1, wherein
the second chip includes
a through hole penetrating the second substrate,
a first electrode provided on an inner wall of the through hole and electrically connected to the second wiring layer, and
a second electrode provided on the inner wall of the through hole at a position facing the first electrode, and electrically connected to the second wiring layer.

6. A chip-stacked device comprising:
a first chip including a first substrate which includes a first outer peripheral surface and a first array surface surrounded by the first outer peripheral surface, and a first wiring layer provided in the first substrate;
a second chip including a second substrate which includes a second outer peripheral surface facing the first outer peripheral surface and a second array surface facing the first array surface, which is surrounded by the second outer peripheral surface, and a second wiring layer provided on the second array surface;
a plurality of connection portions, which is provided between the first array surface and the second array surface, configured to electrically connect the first wiring layer and the second wiring layer;
an insulating member provided between the first array surface and the connection portion;
a first gap formed between the insulating member and the second array surface; and
a second gap formed between the first outer peripheral surface and the second outer peripheral surface,
wherein a height of the second gap is larger than a height of the first gap.

7. The chip-stacked device according to claim 6, wherein
the second substrate further includes a third array surface located on a side opposite to the second array surface, and a third outer peripheral surface located on a side opposite to the second outer peripheral surface, and a step which is formed between the third array surface and the third outer peripheral surface so that the third outer peripheral surface is recessed with respect to the third array surface.

8. The chip-stacked device according to claim 6, wherein
the second chip includes
a through hole penetrating the second substrate,
a first electrode provided on an inner wall of the through hole and electrically connected to the second wiring layer, and
a second electrode provided on the inner wall of the through hole at a position facing the first electrode, and electrically connected to the second wiring layer.

9. A chip-stacked device comprising:
a first chip including a first substrate which includes a first outer peripheral surface and a first array surface surrounded by the first outer peripheral surface, and a first wiring layer provided in the first substrate;
a second chip including a second substrate which includes a second outer peripheral surface facing the first outer peripheral surface, a second array surface facing the first array surface, which is surrounded by the second outer peripheral surface, and a second wiring layer provided on the second array surface;
a plurality of connection portions, which is provided between the first array surface and the second array surface, configured to electrically connect the first wiring layer and the second wiring layer;
an insulating member provided between the second array surface and the connection portion;
a first gap formed between the insulating member and the first array surface; and
a second gap formed between the first outer peripheral surface and the second outer peripheral surface,
wherein a height of the second gap is larger than a height of the first gap.

10. The chip-stacked device according to claim 9, wherein
the second substrate further includes a third array surface located on a side opposite to the second array surface, and a third outer peripheral surface located on a side opposite to the second outer peripheral surface, and a step which is formed between the third array surface and the third outer peripheral surface so that the third outer peripheral surface is recessed with respect to the third array surface.

11. The chip-stacked device according to claim 9, wherein
the second chip includes
a through hole penetrating the second substrate,
a first electrode provided on an inner wall of the through hole and electrically connected to the second wiring layer, and
a second electrode provided on the inner wall of the through hole at a position facing the first electrode, and electrically connected to the second wiring layer.
